(19) United States
(12) Patent Application Publication
(10) Pub. No.: US 2025/0372660 A1
(43) Pub. Date: Dec. 4, 2025

(54) HIGH-ENERGY LITHIUM METAL BATTERIES ACHIEVED BY INORGANIC AND ORGANIC COATINGS

(71) Applicant: BOARD OF TRUSTEES OF THE UNIVERSITY OF ARKANSAS, Little Rock, AR (US)

(72) Inventors: Xiangbo Meng, Fayetteville, AR (US); Kevin Velasquez Carballo, Fayetteville, AR (US); Aiying Shao, Fayetteville, AR (US)

(73) Assignee: BOARD OF TRUSTEES OF THE UNIVERSITY OF ARKANSAS, Little Rock, AR (US)

(21) Appl. No.: 19/223,370

(22) Filed: May 30, 2025

Related U.S. Application Data
(60) Provisional application No. 63/654,754, filed on May 31, 2024.

(51) Int. Cl. H01M 4/62; C23C 16/30; C23C 16/455; C23C 28/04; H01M 4/02; H01M 4/04; H01M 4/131; H01M 4/134; H01M 4/1391; H01M 4/1395; H01M 10/052; H01M 10/42

(52) U.S. Cl. CPC H01M 4/628; C23C 16/305; C23C 16/45555; C23C 28/04; H01M 4/0428; H01M 4/131; H01M 4/134; H01M 4/1391; H01M 4/1395; H01M 10/052; H01M 10/4235; H01M 2004/027; H01M 2004/028

(57) ABSTRACT

The present disclosure pertains to an energy storage device that includes: (1) an anode with a first coating; (2) a cathode with a second coating; and (3) an electrolyte. The present disclosure also pertains to methods of forming an energy storage device by: (1) applying a first coating to an anode; and (2) applying a second coating to a cathode. The first coating may provide an interface between the anode and the electrolyte while the second coating provides an interface between the cathode and the electrolyte.

### CROSS-REFERENCE TO RELATED APPLICATIONS

This application claims priority to U.S. Provisional Patent Application No. 63/654,754, filed on May 31, 2024. The entirety of the aforementioned application is incorporated herein by reference.

### STATEMENT REGARDING FEDERALLY SPONSORED RESEARCH

This invention was made with government support under DE-SC0023439 awarded by the U.S. Department of Energy. The government has certain rights in the invention.

### BACKGROUND

A need exists for the development of energy storage devices with improved energy density, capacity, stability, and safety. Numerous embodiments of the present disclosure aim to address the aforementioned need.

### SUMMARY

In some embodiments, the present disclosure pertains to an energy storage device that includes: (1) an anode with a first coating; (2) a cathode with a second coating; and (3) an electrolyte. Additional embodiments of the present disclosure pertain to methods of forming an energy storage device by: (1) applying a first coating to an anode; and (2) applying a second coating to a cathode. In some embodiments, the first coating provides an interface between the anode and the electrolyte while the second coating provides an interface between the cathode and the electrolyte.

In some embodiments, the first coating includes a metal-containing organic molecule, such as a lithium-containing hydroquinone (LiHQ). In some embodiments, the first coating is applied onto an anode via molecular layer deposition (MLD).

In some embodiments, the second coating includes a metal sulfide, such as Li₂S. In some embodiments, the second coating is applied onto a cathode via atomic layer deposition (ALD).

In some embodiments, the energy storage device includes a battery. In some embodiments, the battery includes, without limitation, lithium metal batteries, Li∥NMC lithium metal batteries (LMBs), lithium ion batteries, or combinations thereof.

### DRAWINGS

FIG. 1 provides an illustration of an energy storage device in accordance with various embodiments of the present disclosure.

FIGS. 2A-2D illustrate the growth of LiHQ via molecular layer deposition (MLD). FIG. 2A provides an illustration of the MLD process of LiHQ using LTB and HQ as precursors. FIG. 2B shows the in situ QCM profile showing a linear growth of LiHQ. FIG. 2C shows the scanning electron microscopy (SEM) images of pristine and LiHQ-coated N-GNS. FIG. 2D shows the high-resolution XPS spectra of LiHQ for O 1s, C 1s, and Li 1s.

FIGS. 3A-3B shows the electrochemical performance of Li∥Li cells. The overpotential profiles of bare and LiHQ-coated Li∥Li symmetric cells with cycles were tested at 2 mA cm⁻² (FIG. 3A) and 5 mA cm⁻² (FIG. 3B) with a fixed areal capacity of 1 mAh cm⁻².

FIGS. 4A-4C show scanning electron microscopy (SEM) observation and XPS analysis on cycled bare and LiHQ-coated Li electrodes. FIG. 4A shows SEM images of the morphological changes of bare Li, LiHQ-50, and LiHQ-75 electrodes. FIGS. 4B-4C show XPS depth profiling of bare Li (FIG. 4B) and LiHQ-100 electrodes (FIG. 4C) after 10 and 50 stripping/plating cycles.

FIGS. 5A-5F show high-resolution XPS spectra of bare Li and LiHQ-100 electrodes after 10 stripping/plating cycles. Shown are C 1s (FIG. 5A), O 1s (FIG. 5B), Li 1s (FIG. 5C), F 1s (FIG. 5D), N 1s (FIG. 5E), and S 2p spectra (FIG. 5F) of both bare Li and LiHQ-100 electrodes tested at 2 mA cm⁻² and a fixed areal capacity of 1 mAh cm⁻².

FIGS. 6A-6D show SEM observations on morphological changes of bare Li and LiHQ-75 electrodes after a 24-h stripping (plating) process. The bare Li electrode (FIGS. 6A-6B) and the LiHQ-75 electrode (FIGS. 6C-6D) were tested at 2 mA cm⁻².

FIGS. 7A-7D show SEM observations on morphological changes of bare Li and LiHQ-75 electrodes after a 48-h stripping/plating (plating/stripping) process. The bare Li electrode (FIGS. 7A-7B) and the LiHQ-75 electrode (FIGS. 7C-7D) were tested at 2 mA cm⁻².

FIGS. 8A-8B show EIS measurements of the bare Li∥Li and LiHQ-75∥LiHQ-75 cells before cycling and after different cycles, cycled at 2 mA cm⁻² and 1 mAh cm⁻².

FIGS. 9A-9B show the effects of the LiHQ coating on the cycling performance of Li∥NMC full cells. The cells of bare Li∥NMC811, LiHQ-75∥NMC811, and LiHQ-75∥Li₂S-20 were tested for their charge/discharge cycling at a rate of 0.5 C (1 C=200 mA g⁻¹) (FIG. 9A) and 1 C (FIG. 9B).

FIGS. 10A-10B show the beneficial effects of LiHQ-75 on the improved cycling number of LiHQ-75∥NMC811 cell, compared to the bare Li∥NMC811 cell, in which Li was 20 μm thick. The cells were cycled at 1 C (1 C=200 mA g⁻¹) in the range of 3.0-4.3 V.

### DETAILED DESCRIPTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that include more than one unit unless specifically stated otherwise.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature and similar materials defines a term in a manner that contradicts the definition of that term in this application, this application controls.

Electrification represents a grand solution to environmental issues (e.g., pollutions and global warming) and energy crises. In the transportation sector, the electric vehicle (EV) transition is underway but still slow, due to the insufficiencies of lithium-ion batteries (LIBs) in energy density, safety, cost, and lifetime. Simply replacing graphite in LIBs with lithium metal (Li) as anodes, the resultant Li metal batteries (LMBs) could significantly increase energy density by ˜50%, ascribed to the extremely high capacity (3860 mAh g⁻¹) and the very low standard electrochemical redox potential (−3.040 V versus the standard hydrogen electrode) of Li. Theoretically, Li metal could couple with any existing (e.g., intercalation-based cathodes) and emerging cathodes (e.g., sulfur and oxygen cathodes) to constitute many promising LMBs.

Although very compelling, Li metal has been suffering two daunting challenges: (1) continuous formation of inhomogeneous solid electrolyte interphase (SEI) with the consumption of both liquid electrolytes and cyclable Li metal, due to the high reactivity of Li, and (2) Li dendritic growth posing serious safety concerns. Even worse, the former prompts the latter while the latter accelerates the former. As a consequence, these two issues have hindered Li anodes from commercialization in the past half century.

In tackling these issues of Li anodes, many strategies have been investigated, such as interface engineering, electrolyte design, and design of three-dimensional Li hosts. Among them, surface coating represents a facile but effective route of interface engineering, which protects Li from contacting electrolytes and thereby avoids side reactions for growth of SEI. However, existing surface coatings suffer from numerous limitations, such as limited ionic conductivity, sub-optimal physical and chemical properties, lack of homogeneity, and limited coating quality.

As such, a need exists for the development of energy storage devices with improved energy density, capacity, stability, and safety. Numerous embodiments of the present disclosure aim to address the aforementioned need.

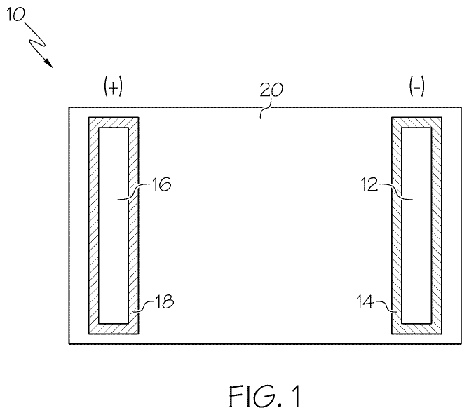

In some embodiments, the present disclosure pertains to an energy storage device. With reference to FIG. 1 for illustrative purposes, energy storage device 10 may include: (1) an anode 12 with a first coating 14; (2) a cathode 16 with a second coating 18; and (3) an electrolyte 20. Additional embodiments of the present disclosure pertain to methods of forming an energy storage device by: (1) applying a first coating 14 to an anode 12; and (2) applying a second coating 18 to a cathode 16. In some embodiments, the first coating 14 provides an interface between the anode 12 and the electrolyte 20 while the second coating 18 provides an interface between the cathode 16 and the electrolyte 20.

Additional embodiments of the present disclosure pertain to energy storage devices that include an anode with a first coating, a cathode, and an electrolyte. Further embodiments of the present disclosure pertain to methods of forming an energy storage device by applying a first coating to an anode. In some embodiments, the first coating provides an interface between the anode and the electrolyte.

Additional embodiments of the present disclosure pertain to energy storage devices that include an anode, a cathode with a second coating, and an electrolyte. Further embodiments of the present disclosure pertain to methods of forming an energy storage device by applying a second coating to a cathode. In some embodiments, the second coating provides an interface between the cathode and the electrolyte.

As set forth in more detail herein, the energy storage devices and methods of the present disclosure can have numerous embodiments.

### Anodes

The energy storage devices of the present disclosure can include various anodes. Additionally, the methods of the present disclosure may modify various anodes. For instance, in some embodiments, the anode includes a lithium anode. In some embodiments, the lithium anode includes a lithium metal layer. In some embodiments, the lithium metal layer can vary significantly in thickness from a few nanometers to several hundreds of microns. In some embodiments, the lithium metal layer may also vary in morphology from two-dimensional flat films to lithium metal particles, or other structures.

### First Coatings

The energy storage devices of the present disclosure can include various first coatings on anodes. Additionally, the methods of the present disclosure may apply various first coatings onto anodes.

For instance, in some embodiments, the first coating includes a metal-containing organic molecule. Metal-containing organic molecules can include various metals. For instance, in some embodiments, the metal includes an alkali metal. In some embodiments, the alkali metal includes, without limitation, Li, Na, K, or combinations thereof.

In some embodiments, the first coating includes the following formula: -//-M-[O-R]ₙ-O-M-//-. In some embodiments, M represents a metal. In some embodiments, R represents the rest of the molecule. In some embodiments, n is an integer of 1 or more. In some embodiments, -//- represents the alternating metal-organic molecule units. In some embodiments, R includes, without limitation, alkyl groups, alkene groups, alkyne groups, carbonyl groups, carboxylic acid groups, alcohol groups, ether groups, phenol groups, amido groups, amide groups, amine groups, methyl groups, ethyl groups, isopropyl groups, isobutyl groups, glycerol groups, aromatic groups, phenyl groups, benzene groups, quinone groups, or combinations thereof. In some embodiments, M includes one or more alkali metals. In some embodiments, M includes, without limitation, Li, Na, K, or combinations thereof. In some embodiments, the first coating includes lithium-containing hydroquinone (LiHQ).

In some embodiments, the first coating is applied onto an anode via molecular layer deposition (MLD). In some embodiments, the MLD process includes depositing at least one metal source and at least one organic molecule onto an anode such that the depositing results in the formation of a metal-containing organic molecule. In some embodiments, the MLD process is repeated a plurality of times to form a plurality of stacked layers of metal-containing organic molecules.

In some embodiments, the metal source for the MLD process includes an alkali metal source. In some embodiments, the alkali metal source includes, without limitation, Li, Na, K, or combinations thereof.

In some embodiments, the metal source for the MLD process includes a lithium source. In some embodiments, the lithium source includes, without limitation, lithium tert-butoxide (LTB, LiO^{t}Bu), lithium hexamethyldisilazide [LiHMDS, Li(N(SiMe3)2)], lithium trimethylsilanolate (LiTMSO, LiOSiMe3), Li(thd) (thd=2,2,6,6-tetramethyl-3,5-heptanedionate), or combinations thereof. In some embodiments, the lithium source includes lithium tert-butoxide (LTB, LiO^{t}Bu).

In some embodiments, the metal source for the MLD process includes a sodium source. In some embodiments, the sodium source includes, without limitation, sodium tert-butoxide (NaO^{t}Bu), sodium trimethylsilanolate (NaTMSO), Li(thd) ((thd=2,2,6,6-tetramethyl-3,5-heptanedionate)), or combinations thereof.

In some embodiments, the metal source for the MLD process includes a potassium source. In some embodiments, the potassium source includes, without limitation, potassium tert-butoxide (KO^{t}Bu), potassium trimethylsilanolate (KTMSO), K(thd) ((thd=2,2,6,6-tetramethyl-3,5-heptanedionate)), or combinations thereof.

In some embodiments, the organic molecule for the MLD process includes a general formula of H—[O—R]ₙ—OH. In some embodiments, n is an integer of 1 or more. In some embodiments, R represents the rest of the molecule. In some embodiments, the organic molecule includes, without limitation, diethanolamine (DEA), triethanolamine (TEA), glycerol (GL), triglycerol (TGL), glycerol propoxylate (GLP), glycerol ethoxylate (GLE), trimethylolpropane ethoxylate (TMPE), polyethylene glycol (PEG), chitosan (CS), hydroquinone (HQ), ethylene glycol (EG), diols, triols, polyols, hydroquinone (HQ), tetrafluorohydroquinone (FHQ), 1,4-benzenedicarboxylic acid (BDC), 2,6-naphthalene dicarboxylic acid (NDC) 1,2-ethanediol (EDO), 1,4-butanediol (BDO), 1,6-hexanediole (HDO), fumaric acid (FC), 2,4-hexadiyene-1,6-diol (HDD), 1,2,4-trihydroxybenzene (THB), lactic acid (LC), 2,2-bis (hydroxymethyl)-1,3-propanediole (BHMPD), alpha-thioglycerol (TGL), 1,2,4-butanetriol (BT), 1,2,5,6-hexanetriol (HT), 2-hydroxymethyl-1,3-propanediol (HMPD), 1-(4-nitrophenyl) glycerol (NPGL), or combinations thereof.

The first coatings of the present disclosure can have various thicknesses. For instance, in some embodiments, the first coatings of the present disclosure can have a thickness ranging from a few angstroms to the micron scale. In some embodiments, the first coatings of the present disclosure can have a thickness of at least 25 nm. In some embodiments, the first coatings of the present disclosure can have a thickness of at least 50 nm. In some embodiments, the first coatings of the present disclosure can have a thickness of at least 75 nm. In some embodiments, the first coatings of the present disclosure can have a thickness of at least 100 nm. In some embodiments, the first coatings of the present disclosure can have a thickness of at least 150 nm.

### Cathodes

The energy storage devices of the present disclosure can include various cathodes. Additionally, the methods of the present disclosure may modify various cathodes. For instance, in some embodiments, the cathode includes lithium nickel manganese cobalt oxides (NMCs). In some embodiments, the NMC includes a layer-structured lithium nickel manganese cobalt oxide. In some embodiments, the NMC includes the following formula: LiNiₓMn_{y}Co_{z}O₂. In some embodiments, x+y+z=1. In some embodiments, the NMC includes, without limitation, LiNi_{1/3}Mn_{1/3}Co_{1/3}O₂ (NMC111), LiNi_{0.4}Mn_{0.4}Co_{-0.2}O₂ (NMC442), LiNi_{0.5}Mn_{0.3}Co_{0.2}O₂ (NMC532), LiNi_{0.6}Mn_{0.2}Co_{0.2}O₂ (NMC622), LiNi_{0.8}Mn_{0.1}Co_{0.1}O₂ (NMC811), or combinations thereof.

### Second Coatings

The energy storage devices of the present disclosure can include various second coatings on anodes. Additionally, the methods of the present disclosure may apply various second coatings onto anodes.

For instance, in some embodiments, the second coating includes a metal sulfide. In some embodiments, the second coating includes a lithium metal sulfide. In some embodiments, the lithium metal sulfide includes the formula LiₓM_{y}S. In some embodiments, M is a metal. In some embodiments, x and y are each a decimal number or an integer number of more than 0. In some embodiments, M is Al, Zr, Zn, or Ga. In some embodiments, the second coating includes Li₂S.

In some embodiments, the second coating is applied onto a cathode via atomic layer deposition (ALD). In some embodiments, the ALD process combines at least one lithium precursor, at least one sulfur precursor, and at least one metal precursor to form a lithium metal sulfide. In some embodiments, the ALD combination step is repeated a plurality of times to form a plurality of stacked layers of lithium metal sulfide.

In some embodiments, the lithium precursor includes, without limitation, lithium tert-butoxide (LTB, LiO^{t}Bu), lithium hexamethyldisilazide (LiHMDS, Li(N(SiMe₃)₂), lithium trimethylsilanolate (LiTMSO, LiOSiMe₃), Li(2,2,6,6-tetramethyl-3,5-heptanedionate) (Li(thd)), or combinations thereof. In some embodiments, the sulfur precursor includes, without limitation, H₂S, di-tert-butyl disulfide (TBDS), or combinations thereof. In some embodiments, the metal precursor includes, without limitation, an aluminum precursor, tris(dimethylamido)aluminum (TDMA-Al), a zinc precursor, diethylzinc (DEZ), a zirconium precursor, tetraki(dimethylamido)zirconium (TDMA-Zr), a gallium precursor, tris(dimethylamido)gallium (TDMA-Ga), or combinations thereof.

The second coatings of the present disclosure can have various thicknesses. For instance, in some embodiments, the second coatings of the present disclosure can have a thickness ranging from a few angstroms to the micron scale. In some embodiments, the second coatings of the present disclosure can have a thickness of at least 0.5 nm. In some embodiments, the second coatings of the present disclosure can have a thickness of at least 2 nm. In some embodiments, the second coatings of the present disclosure can have a thickness of at least 5 nm. In some embodiments, the second coatings of the present disclosure can have a thickness of at least 10 nm. In some embodiments, the second coatings of the present disclosure can have a thickness of at least 50 nm.

### Energy Storage Devices

The energy storage devices of the present disclosure may be in various forms. Additionally, the methods of the present disclosure may be utilized to form various energy storage devices.

For instance, in some embodiments, the energy storage device includes a battery. In some embodiments, the battery includes, without limitation, lithium metal batteries, Li∥NMC lithium metal batteries (LMBs), lithium ion batteries, or combinations thereof.

### Additional Embodiments

Reference will now be made to more specific embodiments of the present disclosure and experimental results that provide support for such embodiments. However, Applicant notes that the disclosure below is for illustrative purposes only and is not intended to limit the scope of the claimed subject matter in any way.

### Example 1. A Novel Polymeric Lithicone Coating for Lithium Metal Anodes

Lithium metal (Li) is commonly regarded as the “holy grail” of rechargeable batteries and can serve as anodes for constituting various high-energy lithium metal batteries (LMBs). However, it suffers from two notorious issues: (1) continuous formation of inhomogeneous solid electrolyte interphase and (2) Li dendritic growth. In this Example, Applicant developed a novel polymeric lithicone via a new molecular layer deposition (MLD) process, using lithium tert-butoxide (LTB) and hydroquinone (HQ) as precursors. Applicant revealed that such an MLD process enabled the resultant LiHQ to grow linearly in a highly controllable and cyclic mode at a growth rate of 4 Å cycle⁻¹. Furthermore, its low process deposition temperature of 150° C. made it possible to practice high-quality coatings over Li anodes.

Applicant demonstrated that, very compellingly, this LiHQ coating could protect Li anodes from corrosion and dendritic growth. As a consequence, this LiHQ coating has enabled Li∥Li symmetric cells an extremely long cyclability up to 8,000 Li-plating/stripping cycles without failure. Moreover, Applicant demonstrated that, coupled with LiNi_{0.8}Mn_{0.1}Co_{0.1}O₂ (NMC811) cathodes, the LiHQ-modified Li anodes could help the resultant Li|NMC811 realize a much better capacity retention and much longer cyclability. Thus, this Example represents a strategic route for developing commercializeable LMBs.

In this Example, Applicant reports a new lithicone via MLD, using lithium tert-butoxide (LTB) and hydroquinone (HQ) as precursors. The resultant LiHQ was coated on Li chips to investigate its effects as a protective coating on Li∥Li symmetric cells and on Li∥Li_{0.8}Mn_{0.1}Co_{0.1}O₂ (NMC811) full cells. Applicant's tests demonstrated that this LiHQ lithicone is very promising as a novel coating and can dramatically improve the cyclability of both Li∥Li and Li∥NMC811 cells. Consequently, this Example paves a feasible pathway for addressing the issues of Li anodes for commercializing LMBs.

### Example 1.1. The Growth of LiHQ

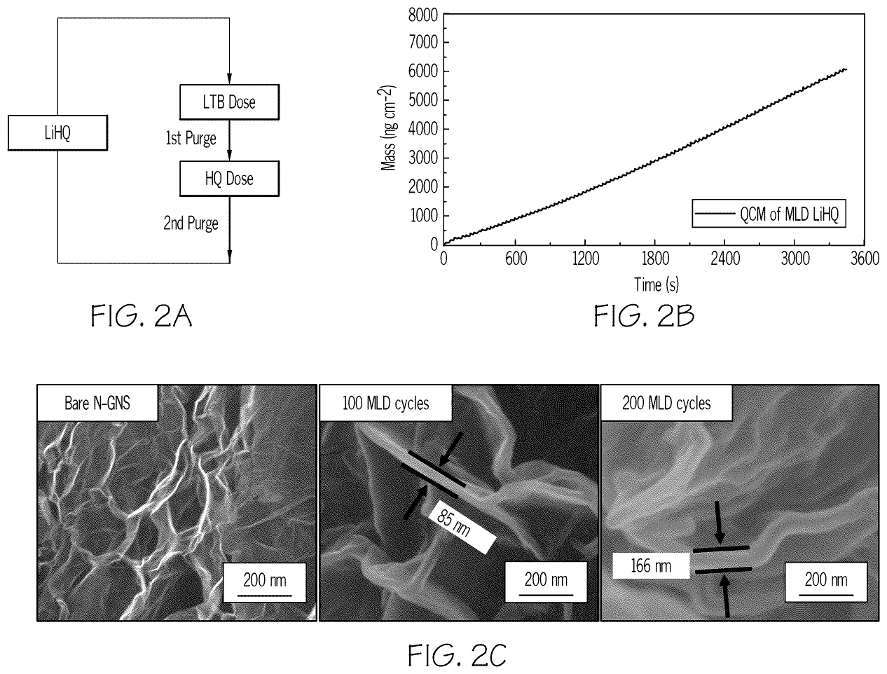

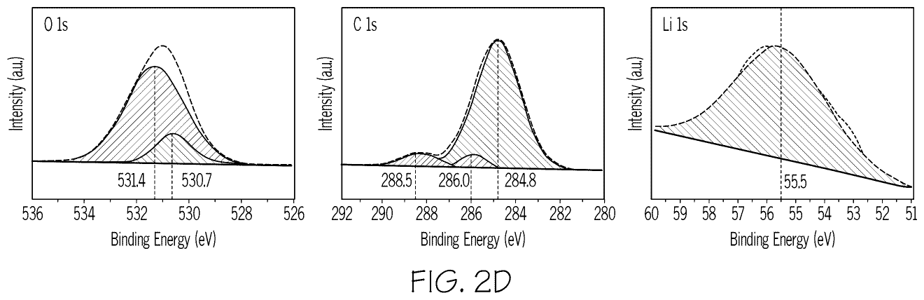

The MLD process of LiHQ lithicone was illustrated in FIG. 2A, and the growth of LiHQ was monitored using an in situ quartz crystal microbalance (QCM). Prior to conducting the QCM measurements of LiHQ, Applicant used atomic layer deposition (ALD) to deposit a repeatable starting surface of Al₂O₃ on the QCM crystal. QCM measurements verified that this MLD process can realize a linear growth of LiHQ (FIG. 2B). Each MLD cycle is highly repeatable and visible in mass gain with the film accumulation. Each dose of LTB and HQ precursors caused a certain mass gain (m₁ and m₂, respectively). The average mass gain of each cycle (Δm=m₁+m₂) is ˜132 ng cm⁻² cycle⁻¹ in the stable growth region.

Applicant deposited the LiHQ over nitrogen-doped graphene nanosheets (N-GNS) with varying MLD cycles (FIG. 2C) to determine its growth per cycle (GPC) at 150° C. Based on the thickness changes of the N-GNS wrinkles after 100 and 200 MLD cycles using a scanning electron microscopy (SEM), the average GPC of the MLD LiHQ is calculated as ˜4 Å cycle⁻¹.

Applicant further postulated the overall reaction of this LiHQ MLD as follows:

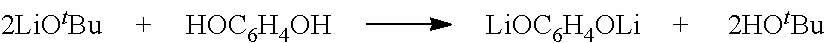

Ideally, the LiHQ is supposed to have a unit structure of LiOC₆H₄OLi. To verify this postulation, Applicant employed X-ray photoelectron spectroscopy (XPS) to analyze LiHQ films deposited on Si wafers, as shown in FIG. 2D. The O 1s spectra show two peaks: one peak at 530.7 eV assigned to O²⁻ in Li—O bonds and one peak at 531.4 eV attributed to C—O—Li. There are three peaks identified with the C 1s spectra: the very strong peak at 284.8 eV assigned to C—C/C—H and two weak peaks at 286.0 and 288.5 eV due to C—O in phenol and O═C—OH, respectively. The Li 1s XPS spectra show only one peak at 55.5 eV attributed to Li—O. According to the XPS analyses, the deposited LiHQ contains 21.9 at. % of Li, 22.7 at. % of O, and 55.4 at. % of C. The atomic ratio of Li, O, and C is consistent to Applicant's postulation on the LiHQ unit structure LiOC₆H₄OLi, i.e., 2:2:6. In addition, synchrotron-based X-ray diffraction (XRD) measurements were conducted on the LiHQ films grown on N-GNS and found no evident peaks, indicating an amorphous phase of the deposited LiHQ.

### Example 1.2. The Protective Effects of LiHQ in Li∥Li Cells

To investigate the protective effects of the MLD LiHQ films on Li metal electrodes, Applicant deposited LiHQ films of various MLD cycles on Li chips (250 μm in thickness) and found that the LiHQ films were very conformal and uniform. The LiHQ-coated Li chips were then assembled into Li|Li cells and examined their stripping/plating cyclability at two current densities, 2 and 5 mA cm⁻², under a fixed areal capacity of 1 mAh cm⁻². To identify the resultant LiHQ-coated Li electrodes, Applicant named them as LiHQ-X, where X is the MLD cycles.

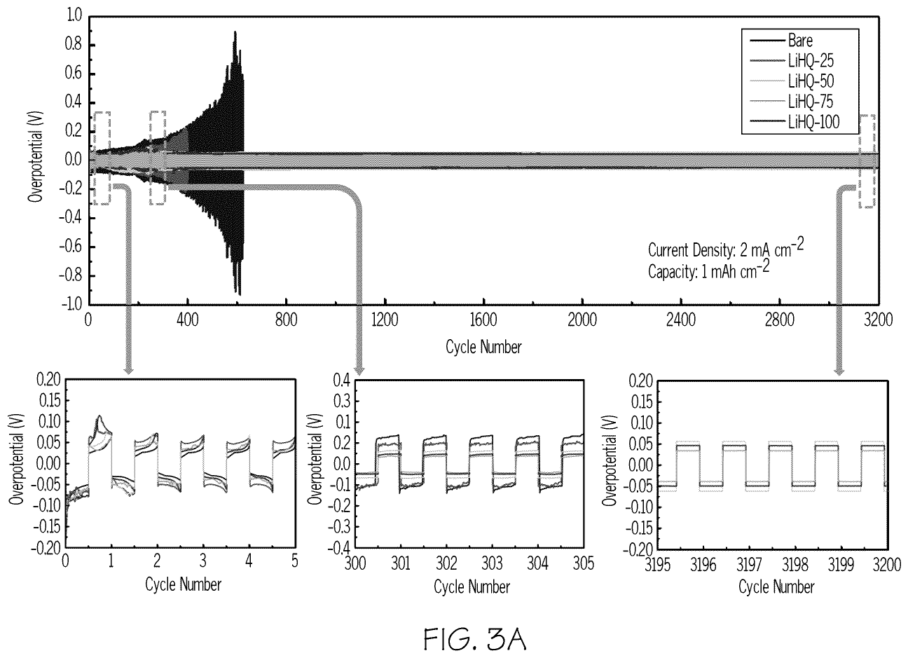

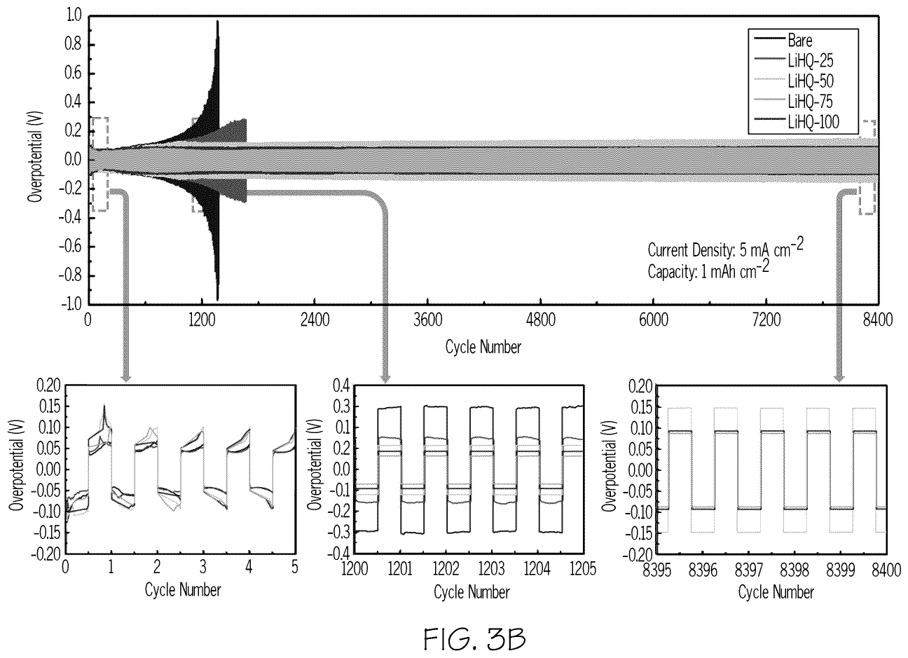

FIG. 3A illustrates the overpotential evolution and cyclability of Li∥Li cells tested at the current density of 2 mA cm⁻². It is easy to observe from the overpotential profiles that, compared to bare Li∥Li cells, LiHQ-25 (˜10 nm thick) improved the cell performance very little. Their overpotential increased continuously from ˜50 to 120 and 100 mV, respectively, within 300 Li-stripping/plating cycles. The ever-increasing overpotential indicates the continuous formation of SEI with increased stripping/plating cycles, due to the unstable surfaces of their Li electrodes of both bare Li∥Li and LiHQ-25∥LiHQ-25 cells.

In sharp contrast to LiHQ-25, however, Applicant found that LiHQ-50 (˜20 nm) or a thicker LiHQ coating could well stabilize the surface of Li electrodes and realize long cyclability of Li∥Li cells with a stable overpotential of ˜55 mV up to 3200 stripping/plating cycles without failures (FIG. 3A). This implies that a 20-nm thick LiHQ coating or thicker is required to protect Li electrodes from corrosion. Particularly, Applicant further noticed that LiHQ-75 (˜30 nm) could further lower the stable overpotential to ˜40 mV while LiHQ-100 (˜40 nm) increased the stable overpotential to ˜50 mV up to 3200 stripping/plating cycles without failures. These findings were further verified by Applicant's tests on Li∥Li cells at a higher current density of 5 mA cm⁻² (FIG. 3B).

In this case, the bare Li∥Li cell could sustain an overpotential at ˜50 mV in 600 Li-stripping/plating cycles but then quickly increased to 1 V by 1300 stripping/plating cycles. In comparison, LiHQ-25 did help sustain the cell overpotential at ˜50 mV for 900 Li-stripping/plating cycles but then showed an evident overpotential increase to ˜300 mV by 1700 stripping/plating cycles. Again, LiHQ-50 demonstrated its remarkable effectiveness in sustaining a stable overpotential at ˜150 mV after 8400 stripping/plating cycles without failures. Even better, LiHQ-75 further lowered the cell overpotential at ˜80 mV stably after 8400 stripping/plating cycles without any failure. Furthermore, LiHQ-100 also could remain a stable overpotential at ˜90 mV after 8400 stripping/plating cycles without failure. All these results in FIGS. 3A and 3B consistently revealed that LiHQ-75 is optimal for achieving the best cell performance of Li∥Li cells.

### Example 1.3. The Underlying Mechanisms of the LiHQ Protection

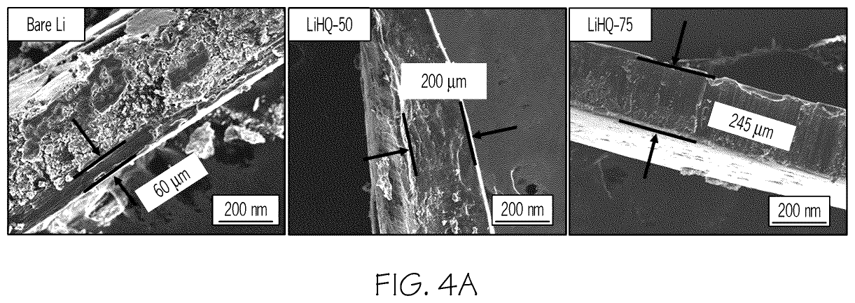

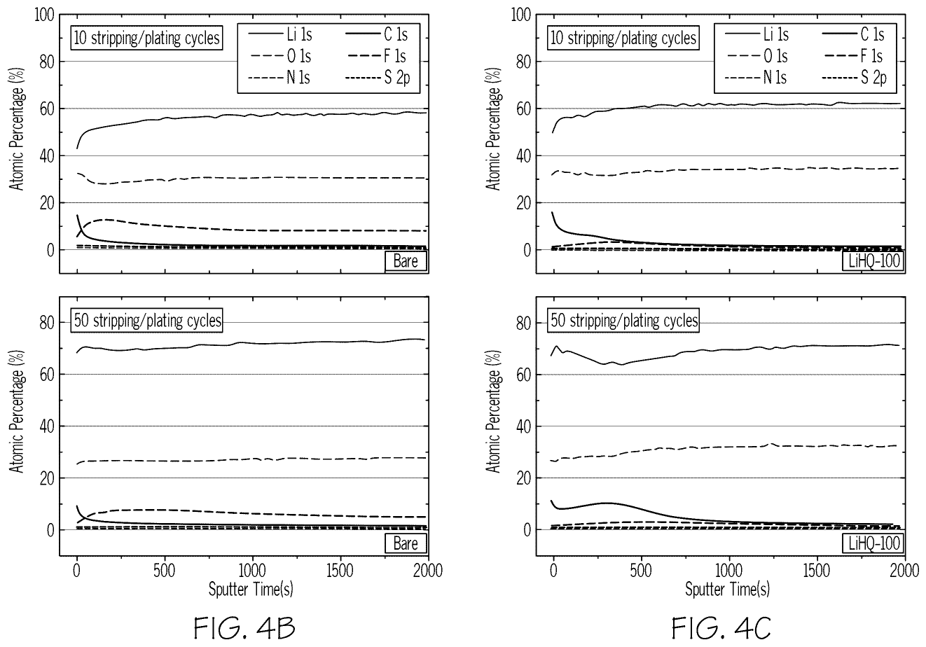

The compelling performance of LiHQ-coated Li∥Li cells prompted Applicant to understand the underlying mechanisms of the protective effects of the LiHQ coatings. To this end, Applicant investigated some cycled Li electrodes using SEM and XPS. As shown in FIG. 4A, SEM revealed the cross-sections of three Li electrodes (bare Li, LiHQ-50, and LiHQ-75) after 200 stripping/plating cycles at 2 mA cm⁻² and 1 mAh cm⁻². One can easily observe that, compared to the cross section of bare Li metal (250 μm thick) before cycling, the bare electrode has been significantly corroded with the evident formation of SEI. In comparison, the LiHQ coatings have evidently protected Li from the corrosions, and there was more Li retained with an increased LiHQ coating thickness. Remarkably, the cross-section of the cycled LiHQ-75 was nearly intact, and the thickness of fresh Li layer almost keeps unchanged after cycling (FIG. 4A). Thus, Applicant concluded that the optimal coating thickness to protect Li electrodes from corrosion is ˜75 cycles of LiHQ via MLD.

Applicant further utilized XPS to study the composition of cycled bare and LiHQ-coated Li electrodes. As shown in FIG. 4B, bare Li electrodes (250 μm in thickness) cycled for 10 and 50 stripping/plating times were analyzed by XPS depth profiling. Within a 2000-s sputtering, Applicant could clearly observe Li (44-58 at. %), oxygen (O, 29-32 at. %), and fluorine (F, 8-12 at. %) elements while N and S were very little, ˜0.3-1 at. % and ˜1-2 at. %, respectively. The carbon (C) content was very remarkable at the surface but dropped quickly from ˜14-2 at. %. These data implied that there was a thick SEI layer formed on the bare Li electrode after 10 stripping/plating cycles. The detected F, C, and O elements are likely from the salt of LiTFSI and the solvents of DOL and DME or their decomposed products. Within the 200-s sputtered layer, particularly, both C and O decrease in their atomic contents while Li and F increase in its atomic contents. Based on this fact, Applicant postulate that the top layer may be mainly organic while the underneath layer may be mainly inorganic. In other words, the SEI layer has a bilayered organic-inorganic structure, as widely reported in literature. After 50 stripping/plating cycles, the bare Li electrode showed the similar results (FIG. 4B). Very differently, the LiHQ-100 electrode after 10 stripping/plating cycles, (FIG. 4C) exhibited much less F (˜1-3 at. %) in the 2000-s sputtered depth while had considerable Li (˜44-58 at. %) and O (˜28-31 at. %).

This implies much less decomposition of LiTFSI. Particularly, Applicant also observed a sharp drop of C from ˜14-2 at. % in a 400-s sputtering layer. The depth profile analyses of the LiHQ-100 protection layer (˜40 nm) show that the LiHQ-100 electrode has experienced less formation of SEI. After 50 stripping/plating cycles, the LiHQ-100 electrode showed the similar results (FIG. 4C).

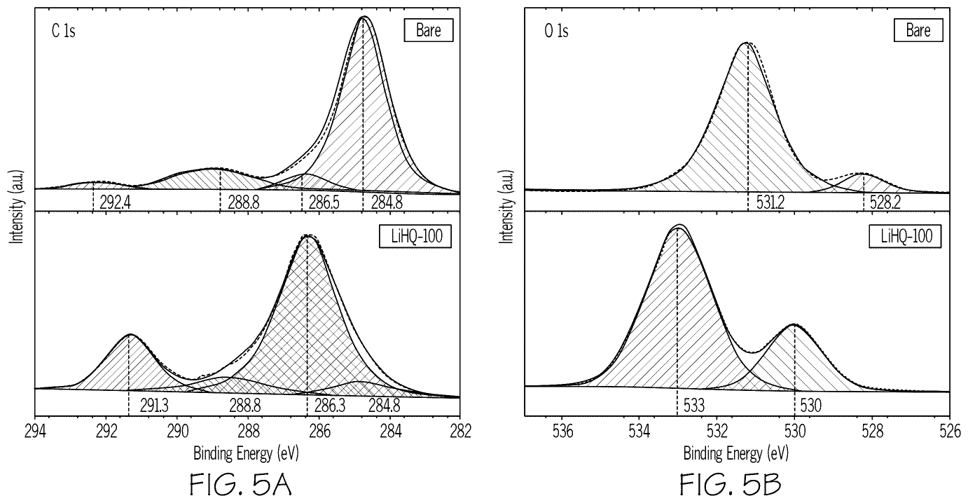

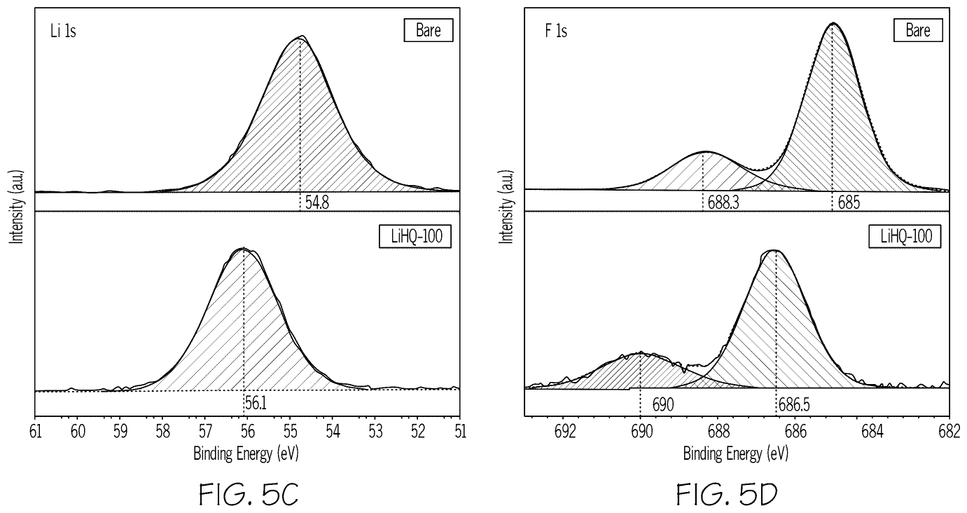

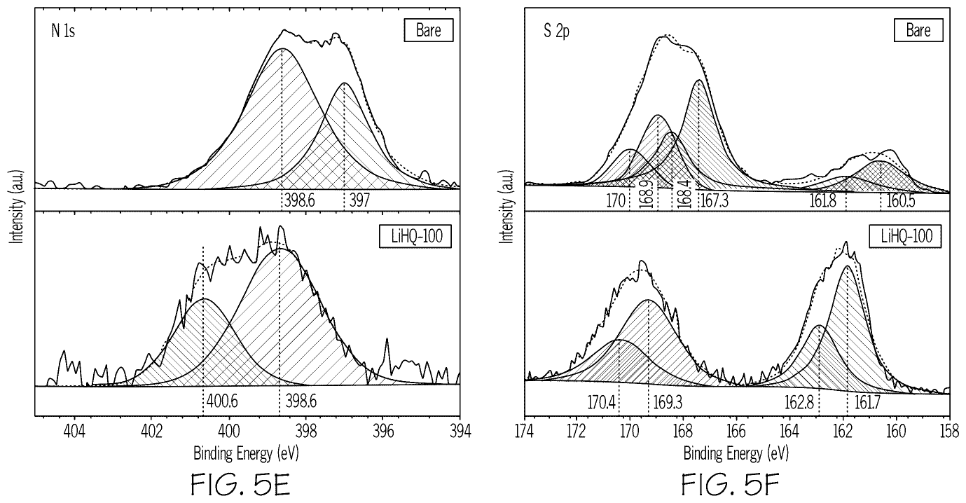

To further clarify the above postulations, Applicant also conducted high-resolution XPS analysis on the cycled bare and LiHQ-100 electrodes after 10 and 50 stripping/plating cycles, as illustrated in FIGS. 5A-5F. To facilitate Applicant's comparisons on the bare and LiHQ-100 electrodes after 10 stripping/plating cycles, Applicant placed the XPS spectra obtained from the bare Li electrode and LiHQ-100 electrode together for each of C, O, Li, F, S, and N 1s, as illustrated in FIGS. 5A-5F. The spectra of the bare Li electrode are signified by Bare while the ones of LiHQ-100 are indicated by LiHQ-100. For the bare Li electrode, the XPS spectra of C 1s in FIG. 5A revealed a very strong peak at 248.8 eV corresponding to the organic components of C—C and C—H as well as two weak peaks for C—O at 286.5 eV and for C═O at 288.8 eV. These XPS features imply that DOL and DME have experienced significant reduction. The underlying mechanisms for the reduction of both DOL and DME are C—O bond cleavage and radical attacks. Specifically, the reduction of DOL and DME could be described as follows:

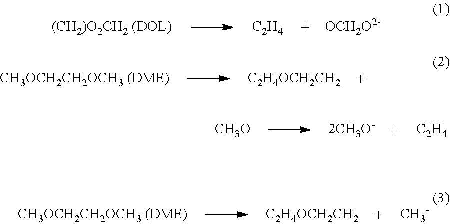

In addition, there also has a peak at 292.4 eV assigned to —CF₃, which is related to LiTFSI or its degraded production (e.g., Li₂NSO₂CF₃):

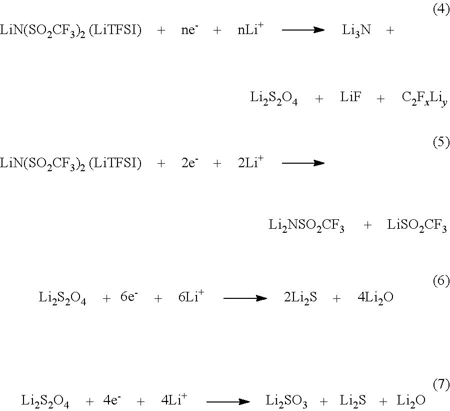

Dissolved Li⁺ ions could further react with the degraded solvents to form Li₂CO₃. This has been confirmed by the spectra of O 1s (FIG. 5B), revealing two peaks for Li₂CO₃ at 531.2 eV and for Li₂O at 528.2 eV. In addition, the spectra of Li 1s (FIG. 5C) disclosed Li₂CO₃ at 54.8 eV and F 1s (FIG. 5D) showed —CF₃ at 688.3 eV and LiF at 685 eV. From the spectra of N 1s (FIG. 5E), Applicant identified a reduced LiTFSI, Li₂NSO₂CF₃ at 398.6 eV and Li₃N at 397 eV. From the spectra of S 2p (FIG. 5F), Applicant determined LiTFSI at both 170 and 168.9 eV, Li₂NSO₂CF₃ at both 168.4 and 167.3 eV, LiₓS at 161.8 eV, and Li₂S at 160.5 eV. To take all these together, Applicant can conclude that the solvents (DOL and DME) and the salt have experienced serious reduction with the formation of an SEI layer consisting of organic (e.g., C₂H₄OCH₂CH₂) and inorganic products (e.g., LiF, Li₂CO₃, Li₂O, and Li₃N) while the bare Li electrode suffered from corrosion with the loss of cyclable Li. These results are consistent to the results of FIG. 4A and FIG. 4B.

In contrast, XPS analysis revealed different results on the cycled LiHQ-100 electrode after 10 stripping/plating cycles (FIGS. 5A-5F). The spectra of C1s (FIG. 5A) revealed a very strong peak of C—O at 286.3 eV and two weak peaks of C═O (288.8 eV) and C—C/C—H (284.8 eV), implying little decomposition of the solvents. Furthermore, Applicant also noticed an evident peak of —CF₃ at 291.3 eV due to LiTFSI or reduced LiTFSI. Furthermore, the spectra of O 1s did not show any evidence of the Li₂CO₃ formation, but were witnessed with a strong peak of C—O at 533 eV, consistent to the spectra of C 1s, and a relatively low peak at 530 eV assigned to Li—O. These may be ascribed to the LiHQ coating, at least partially. Additionally, the spectra of Li 1s showed a single peak (56.1 eV) rooted from LiTFSI. The spectra of F 1s revealed two peaks (690 and 686.5 eV) related to LiTSFI. Moreover, the spectra of N 1s disclosed two peaks due to LiTFSI (400.6 eV) and Li₂NSO₂CF₃ (398.6 eV). The spectral of S 2p displayed two peaks (170.4 and 169.3 eV) assigned to LiTFSI and two peaks for LiₓS (162.8 eV) and Li₂S (161.7 eV). To summarize, one is easy to form a conclusion that the LiHQ-100 coating has significantly protected the solvents and the LiTFSI salt from serious decomposition. This is supported by little degraded products (e.g., LiF and Li₂CO₃). It also disclosed that the LiHQ-100 coating may be porous. Consequently, the LiTFSI salt and the solvents (DOL and DME) have remained in the LiHQ coating and were mainly detected.

Observing the XPS spectra of the cycled bare Li and LiHQ-100 electrodes after 50 stripping/plating cycles and comparing them with the results in FIGS. 5A-5F, Applicant could further conclude that the surface composition of the bare Li electrode evolved with stripping/plating cycles while the surface composition of the LiHQ-100 electrode was relatively stable and did not change evidently. Again, these results confirmed that the LiHQ coating is very effective on protecting Li electrodes from degradation. This also underlies the excellent cyclability of LiHQ-coated Li∥Li cells in FIGS. 3A-3B.

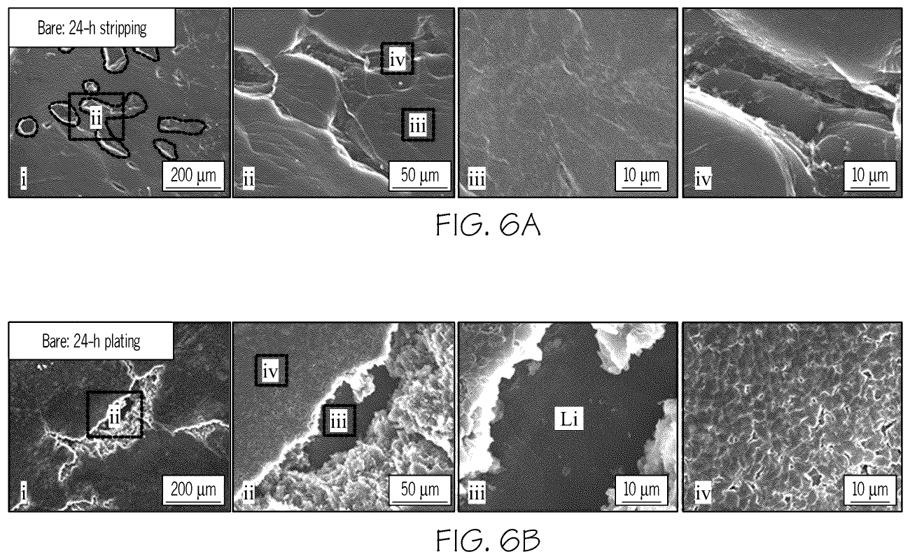

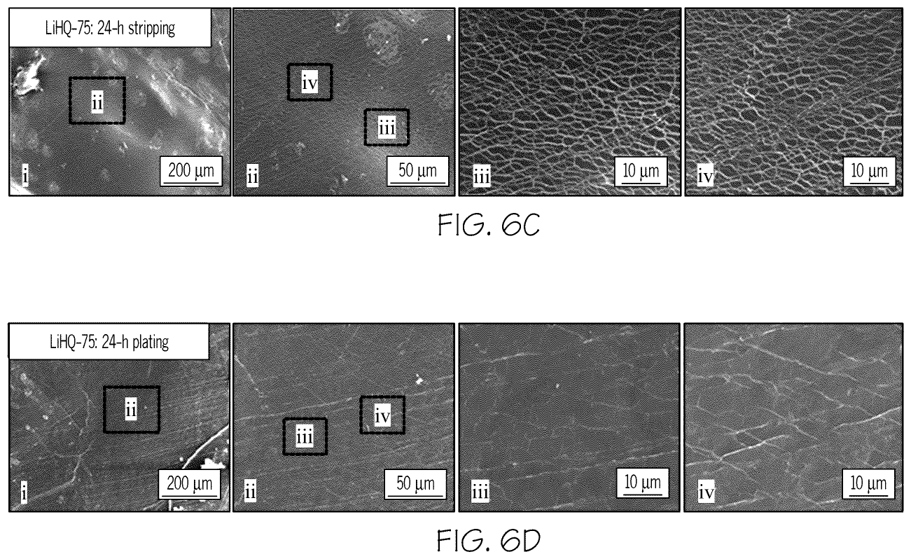

To further probe the excellent protection of this LiHQ coating, Applicant also conducted a study under an extremely high capacity, 48 mAh cm⁻² and observed the morphological changes of Li electrodes (250 μm in thickness). In the study, both bare Li∥Li and LiHQ-75|LiHQ-75 cells were conducted for one 24-h stripping (plating) process at a current density of 2 mA cm⁻² (i.e., an areal capacity of 48 mAh cm⁻²). Subsequently, the surface of the two bare Li electrodes and the two LiHQ-75 electrodes were observed using SEM (FIGS. 6A-6D). Applicant noticed that, after a 24-h stripping, there are numerous craters (as circled by dashed lines) surrounded by highlands (the areas other than the circles) on the bare Li electrode (FIGS. 6A(i) and 6A(ii)). The highlands are smooth (FIG. 6A(iii)) while the craters contain numerous microholes (FIG. 6A(iv)). The similar results also have been reported in Applicant's previous studies. On the opposite bare Li electrode, meanwhile, a 24-h plating deposited a thick dendritic Li layer (FIGS. 6B(i) and 6B(ii)). Particularly, it could be clearly identified that the deposited dendritic Li layer is separated from the bare Li electrode (FIG. 6B(ii)). The bare Li was flat and smooth (FIG. 6B(iii)) while the deposited Li was in micron-sized dendritic structures (FIG. 6B(iv)). Applicant postulated that the separation of the bare Li surface and the deposited dendritic layer is due to their SEI layers existing on their surfaces. In sharp contrast, there had no craters and bumps observed on the surface of the LiHQ-75 electrode after a 24-h stripping (FIG. 6C). Applicant noticed numerous fractures, which were mainly caused during the mechanical cell assembling instead of stripping/plating cycles.

On the opposite LiHQ-75 electrode, Applicant did not observe any evident deposition of Li dendrites but witnessed a clean and smooth surface with factures similar to the stripped side (FIG. 6D). These stripping/plating results of the LiHQ-75 electrodes clearly demonstrated that the LiHQ coating has well protected Li from formation SEI and Li dendrites and exhibited a good ion conduction to let Li⁺ ions pass through during the stripping (plating) process.

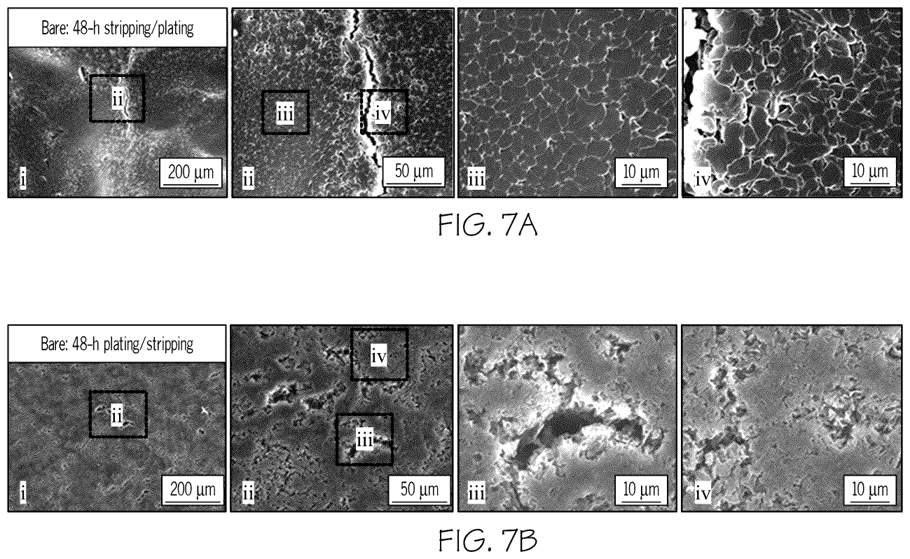

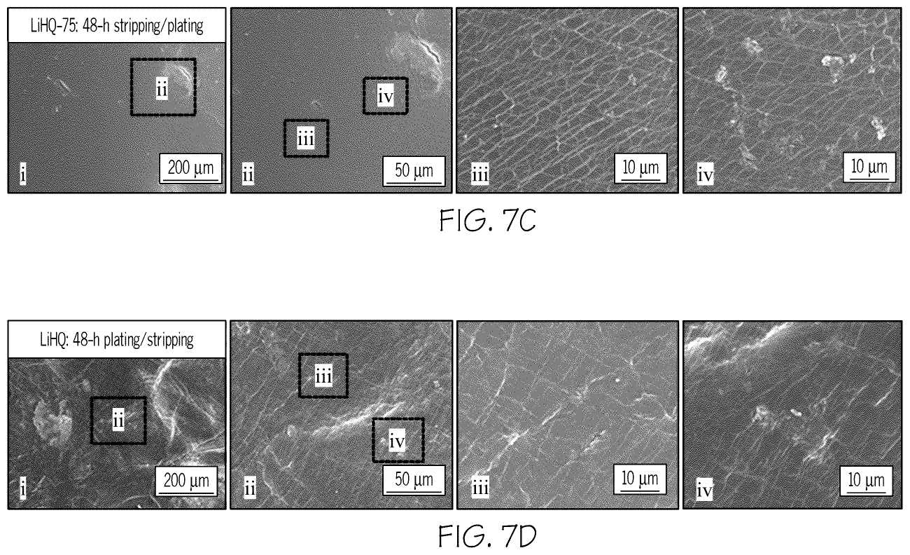

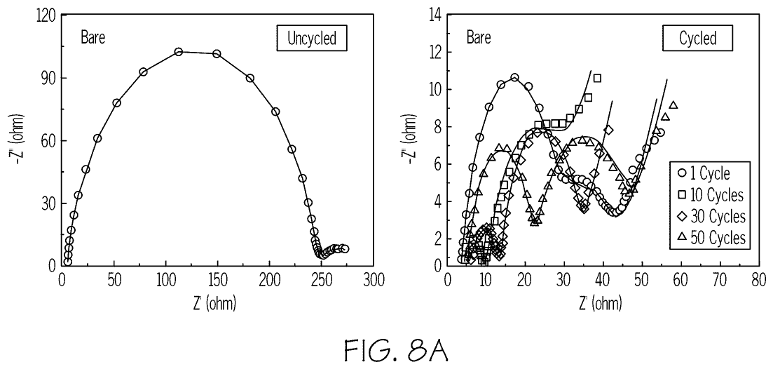

To further examine the protection effects of the LiHQ coating, Applicant then conducted one 48-h stripping/plating cycle (i.e., a 24-h stripping followed by a 24-h plating) to bare Li∥Li and LiHQ-75∥LiHQ-75 cells. As shown in FIG. 7A, the bare Li electrode was covered with a thick dendritic Li layer after a 48-h stripping/plating cycle, similar to the surface morphology after a 24-h plating shown in FIG. 7B. The opposite bare Li after a 48-h plating/stripping cycle (FIG. 7B) exhibited a similar appearance as after a 24-h stripping of the bare Li electrode shown in FIG. 7A, featuring numerous craters surrounded by highlands. Different from the bare Li electrode after a 24-h stripping (FIG. 7A), however, the bare Li electrode was covered by a porous SEI layer after a 48-h plating/stripping cycle (FIG. 7B). The porous SEI layer was created by the former plating process. Very impressively, the two LiHQ-75 electrodes after a 48-h stripping/plating (FIG. 7C) or plating/stripping cycle (FIG. 7D) both were still clean and smooth with fractures, similar to the surface after a 24-h plating in FIGS. 6D and 6C. This study well demonstrated that the optimal ion conduction of the LiHQ coating allows Li⁺ ions to pass through during stripping/plating processes. The LiHQ coating apparently is chemically and electrochemically stable to avoid SEI formation and has good mechanical properties enabling inhibition of Li dendrites.

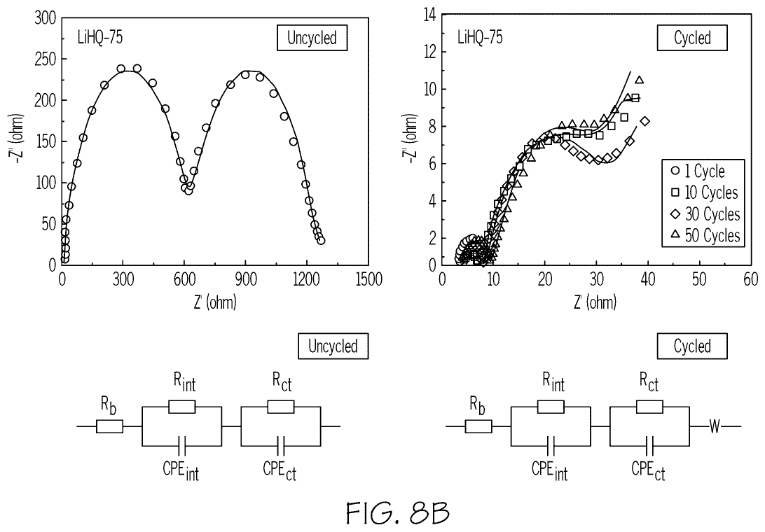

To verify the fast-ion conducting nature of this LiHQ coating, Applicant studied the evolution of cell impedance with stripping/plating cycles (FIGS. 8A-8B). The equivalent circuits are proposed for different cells. R_{b}, Rᵢₙₜ, and R_{ct} are the bulk resistor, the interfacial resistor, and charge transference resistor, respectively. CPE represents a constant phase element and W denotes a Warburg element. Prior to Li stripping/plating cycles, the uncycled the bare Li∥Li cell has an impedance of ˜250Ω while the uncycled LiHQ-75∥LiHQ-75 cell has an impedance of ˜600Ω due to the LiHQ coatings. However, after first stripping/plating cycle, the Rᵢₙₜ of the bare Li∥Li cell becomes much larger than that of the LiHQ-75∥LiHQ-75. This might be caused by the massive formation of SEI on the bare Li surface.

The rapid drop of Rᵢₙₜ in the bare Li∥Li cell after the initial cycle is likely due to the electrode activation. Thereafter, the Rᵢₙₜ and R_{ct} of the bare Li∥Li and LiHQ-75∥LiHQ-75 cells were comparable within 30 stripping/plating cycles, but the two values of the bare Li∥Li became evidently larger than those of the LiHQ-75∥LiHQ-75 after 50 cycles. Moreover, the Rᵢₙₜ and R_{ct} of the LiHQ-75∥LiHQ-75 cells were very stable with cycles. These results again confirmed that the LiHQ coating is chemical and electrochemically stable and therefore could stabilize the Li interface during the Li stripping/plating cycles.

### Example 1.4. The Improvement of Li∥NMC811 Full Cells

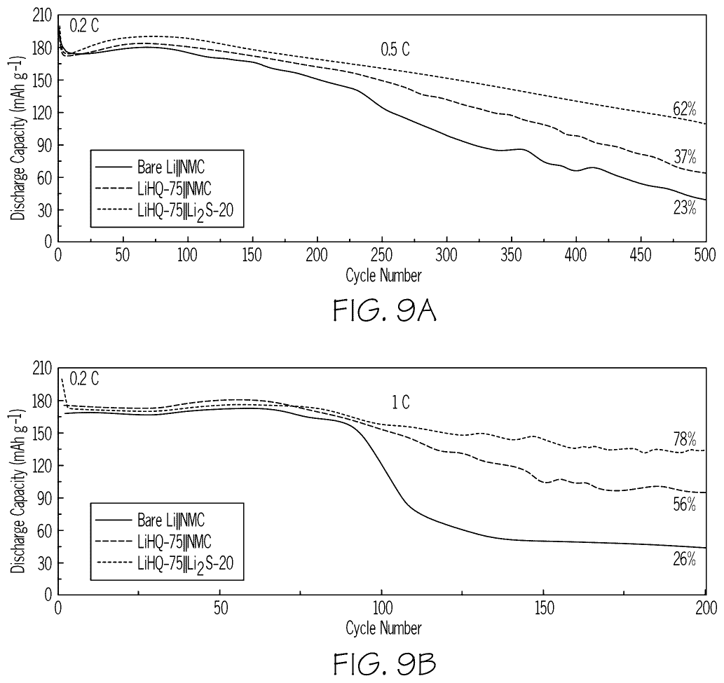

Given the optimal performance of the LiHQ-coated Li electrodes, Applicant was encouraged to examine their benefits on Li∥NMC811 full cells (FIGS. 9A-9B). The Li metal was 250 μm thick. Three types of full cells were formed: (1) bare Li∥NMC811, (2) LiHQ-75∥NMC811, and (3) LiHQ-75|Li₂S-20, where LiHQ-75 indicates Li anodes coated by a 75-cycle MLD LiHQ coating and Li₂S-20 signifies NMC811 cathodes coated by a 20-cycle ALD Li₂S coating. The Li₂S-coated NMC811 cathodes have been reported in one of Applicant's previous studies, in which a 20-cycle ALD Li₂S enabled the best performance. These full cells were first activated for 2 cycles at 0.2 C (1 C=200 mA g⁻¹) and then they were cycled at 0.5 (FIG. 9A) and 1 C (FIG. 9B) for both charge/discharge processes in the voltage range of 3.0-4.3 V, respectively. When cycled at 0.5 C (FIG. 9A), Applicant noticed that, after 500 charge/discharge cycles, the capacity retention is 23%, 37%, and 62% for bare Li∥NMC811, LiHQ-75∥NMC811, and LiHQ-75∥Li₂S-20 cells, respectively.

Compared to the bare Li∥NMC811 cell, the LiHQ-75∥NMC811 has improved by ˜60% and LiHQ-75∥Li₂S-20 has improved by ˜170% in capacity retention. These results clearly indicate that the LiHQ-protected Li anodes are very beneficial for improving the performance of Li∥NMC811 full cells. Coupling with Applicant's ALD-modified NMC811, even more encouragingly, Applicant could maximize the benefits of both ALD and MLD coatings. The charge/discharge profiles and dQ/dV profiles of these cells clearly showed the benefits to the cell stability due to the MLD LiHQ coating as well as the ALD Li₂S coating. Testing these full cells at a higher rate of 1 C (FIG. 9B), Applicant again confirmed the benefits of this LiHQ coating on Li anodes. It improved the LiHQ-75∥NMC811 by 115% and the LiHQ-75∥NMC811 by 200% in capacity retention after 200 charge/discharge cycles.

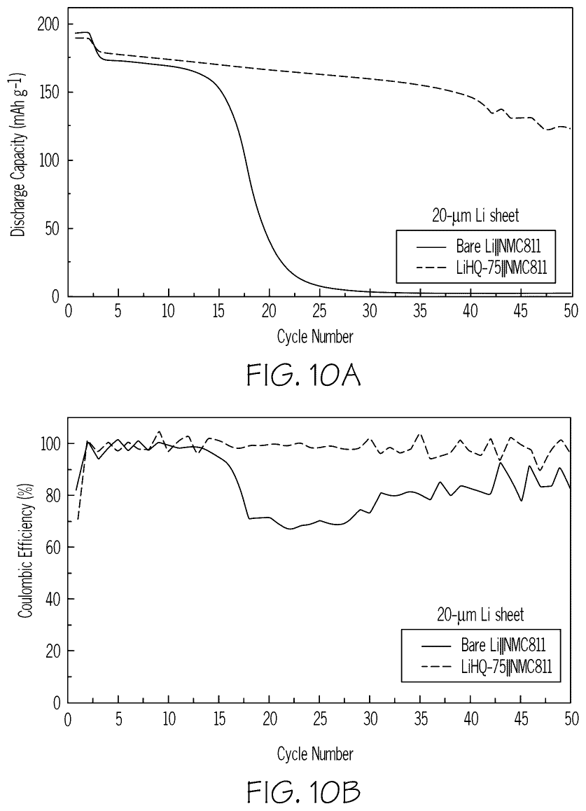

Furthermore, Applicant also demonstrated the LiHQ-75 coating's protection effects on ultrathin Li metal sheets (20 μm thick), as shown in FIGS. 10A-10B. Using this 20-μm thick Li metal as anodes, the LiHQ-75∥NMC811 cell could realize a cyclability three times longer than that of bare Li∥NMC811 cell (FIG. 10A) and a much higher Coulombic efficiency (FIG. 10B). The bare Li∥NMC811 cell started to drop quickly in capacity after ˜15 cycles while the LiHQ-75∥NMC811 cell still could sustain a very high capacity of ˜125 mAh g⁻¹ after 50 cycles (FIG. 10A). Accordingly, the bare Li∥NMC811 cell started to drop quickly in Coulombic efficiency after ˜15 cycles while the LiHQ-75∥NMC811 cell could always sustain a very high and stable Coulombic efficiency of ˜100% in 50 cycles (FIG. 10B).

### Example 1.5. Conclusion

In this Example, Applicant for the first time developed a novel lithicone, i.e., LiHQ, using MLD at a moderate temperature of 150° C. with an average GPC of ˜4 Å cycle⁻¹. This LiHQ MLD coating showed exceptional protection on Li electrodes (i.e., remarkable suppression of the formation of SEI and Li dendrites). Furthermore, Applicant's results indicated that the LiHQ MLD film is electrically insulating and ionically conductive. These favorable merits of this LiHQ coating contributed to the ultra-long Li stripping/plating cyclability in Li∥Li symmetric cells. In addition, the LiHQ coating played important roles in improving the performance of Li∥NMC811 full cells. Particularly, Applicant demonstrated that this LiHQ coating on Li anodes could work synergically with the ALD Li₂S coating to best improve the performance of Li∥NMC811 full cells. Therefore, this work provides a facile and effective strategy by combining both ALD and MLD coatings together to develop high-performance Li∥NMC LMBs.

### Example 1.6. MLD Processes

Using a commercial MLD system (Savannah 200, Ultratech Inc., MA, USA) with argon (Ar) as the carrier gas, the MLD process of the LiHQ lithicone has been developed in this Example. LTB (LiO^{t}Bu, Sigma-Aldrich, USA) as the Li source was preheated in a bubbler at 150° C. for a sufficient vapor supply, while HQ (Sigma-Aldrich, USA) was maintained in stainless steel cylinders at 150° C. This MLD system was integrated with an Ar-filled glove box (having an oxygen and water level lower than 1 ppm). The timing sequence of a single MLD cycle was typically in a sequence of t₁-t₂-t₃-t₄, corresponding to the LTB dose, the first Ar purge, the HQ dose, and the second Ar purge, respectively. The precursor dosing time of t₁ and t₃ was optimized as 5 and 2 s, respectively, while the purge time of t₂ and t₄ was optimized as 60 s. During the MLD process, the Ar gas flow was remained at 20 sccm. Li chips were uniformly coated with LiHQ films for 25, 50, 75, and 100 MLD cycles. The resultant MLD-coated Li anodes were then named as LiHQ-25, LiHQ-50, LiHQ-75, and LiHQ-100, respectively. Accordingly, the uncoated Li electrode was signified as bare Li.

The MLD process has been studied using an in situ quartz crystal microbalance (QCM). The QCM measurements were conducted using a gold sensor crystal (Inficon, USA) and enabled the visualization of the MLD growth in a time-resolved mass change in ng cm⁻². To establish a repeatable QCM surface for studying the MLD process, Applicant pre-deposited an Al₂O₃ layer on the QCM via ALD, using trimethylaluminum (TMA) and water as precursors with the timing sequence 0.05-10-0.05-10 s.

### Example 1.7. NMC Electrode Preparation

The NMC811 electrode laminates in this Example contain 86 wt % NMC811 powder (MSE Supplies, USA), 7 wt % polyvinylidene fluoride (PVDF, HSV900, MTI Corporation, USA), and 7 wt % carbon black (Timical Super C65). To fabricate the laminates, a slurry was first prepared by mixing NMC811 powders, PVDF, and carbon black with a suitable amount of 1-methyl-2-pyrrolidinone (NMP, 99.5%, SigmaAldrich) homogenously using a mixer (THINKY, AR-100). Then, the slurry was cast on Al foils. The resultant NMC laminates were first vaporized completely in air and further dried in vacuum at 100° C. for 10 h. The mass loading of the as-prepared NMC811 is ˜7.0 mg cm⁻².

### Example 1.8. Li₂S ALD Coating on NMC

In this Example, both the Li₂S ALD process and the LiHQ MLD process were performed using the same system. The ALD-Li₂S coating was deposited on prefabricated NMC811 laminates directly, using LTB and hydrogen sulfide (4 at. % H₂S balanced by Ar, Airgas) as precursors. To supply sufficient vapor, the solid LTB was heated to 150° C. in a stainless steel bubbler. A single cycle of the Li₂S ALD consisted of four successive steps: (1) a 5 s dose of LTB, (2) a 10 s purge, (3) a 0.5 s dose of H₂S, and (4) a 10 s purge. NMC electrodes were conformally coated with Li₂S films for 20 ALD cycles. The resultant Li₂S-coated NMC811 was named as Li₂S-20.

Without further elaboration, it is believed that one skilled in the art can, using the description herein, utilize the present disclosure to its fullest extent. The embodiments described herein are to be construed as illustrative and not as constraining the remainder of the disclosure in any way whatsoever. While the embodiments have been shown and described, many variations and modifications thereof can be made by one skilled in the art without departing from the spirit and teachings of the invention. Accordingly, the scope of protection is not limited by the description set out above, but is only limited by the claims, including all equivalents of the subject matter of the claims. The disclosures of all patents, patent applications and publications cited herein are hereby incorporated herein by reference, to the extent that they provide procedural or other details consistent with and supplementary to those set forth herein

1. An energy storage device comprising:
an anode comprising a first coating, wherein the first coating comprises a metal-containing organic molecule;
a cathode comprising a second coating, wherein the second coating comprises a metal sulfide; and
an electrolyte
wherein the first coating provides an interface between the anode and the electrolyte while the second coating provides an interface between the cathode and the electrolyte.

2. The energy storage device of claim 1, wherein the anode comprises a lithium anode.

3. The energy storage device of claim 1, wherein the first coating comprises the following formula: 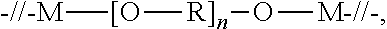
wherein M represents a metal,
wherein R represents the rest of the molecule,
wherein n is an integer of 1 or more, and
wherein -//- represents the alternating metal-organic molecule units.

4. The energy storage device of claim 3, wherein R is selected from the group consisting of alkyl groups, alkene groups, alkyne groups, carbonyl groups, carboxylic acid groups, alcohol groups, ether groups, phenol groups, amido groups, amide groups, amine groups, methyl groups, ethyl groups, isopropyl groups, isobutyl groups, glycerol groups, aromatic groups, phenyl groups, benzene groups, quinone groups, or combinations thereof.

5. The energy storage device of claim 3, wherein M comprises one or more alkali metals selected from the group consisting of Li, Na, K, or combinations thereof.

6. The energy storage device of claim 1, wherein the first coating comprises lithium-containing hydroquinone (LiHQ).

7. The energy storage device of claim 1, wherein the first coating is applied via molecular layer deposition (MLD).

8. The energy storage device of claim 1, wherein the cathode comprises lithium nickel manganese cobalt oxides (NMCs), wherein the NMC comprises a layer-structured lithium nickel manganese cobalt oxide, and wherein the NMC comprises the following formula:

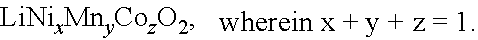

9. The energy storage device of claim 8, wherein the NMC is selected from the group consisting of LiNi_{1/3}Mn_{1/3}Co_{1/3}O₂ (NMC111), LiNi_{0.4}Mn_{0.4}Co_{-0.2}O₂ (NMC442), LiNi_{0.5}Mn_{0.3}Co_{0.2}O₂ (NMC532), LiNi_{0.6}Mn_{0.2}Co_{0.2}O₂ (NMC622), LiNi_{0.8}Mn_{0.1}Co_{0.1}O₂ (NMC811), or combinations thereof.

10. The energy storage device of claim 1, wherein the second coating comprises a lithium metal sulfide, wherein the lithium metal sulfide comprises the formula LiₓM_{y}S, wherein M is a metal, and wherein x and y are each a decimal number or an integer number of more than 0.

11. The energy storage device of claim 10, wherein M is Al, Zr, Zn, or Ga.

12. The energy storage device of claim 1, wherein the second coating comprises Li₂S.

13. The energy storage device of claim 1, wherein the second coating is applied via atomic layer deposition (ALD).

14. The energy storage device of claim 1, wherein the energy storage device comprises a battery selected from the group consisting of lithium metal batteries, Li∥NMC lithium metal batteries (LMBs), lithium ion batteries, or combinations thereof.

15. A method of forming an energy storage device, said method comprising:
applying a first coating to an anode, wherein the first coating comprises a metal-containing organic molecule; and
applying a second coating to a cathode, wherein the second coating comprises a metal sulfide,
wherein the first coating provides an interface between the anode and the electrolyte while the second coating provides an interface between the cathode and the electrolyte.

16. The method of claim 15, wherein the first coating comprises the following formula: 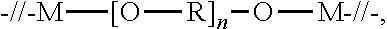
wherein M represents a metal,
wherein R represent the rest of the molecule,
wherein n is an integer of 1 or more, and
wherein -//- represents the alternating metal-organic molecule units.

17. The method of claim 16,
wherein R is selected from the group consisting of alkyl groups, alkene groups, alkyne groups, carbonyl groups, carboxylic acid groups, alcohol groups, ether groups, phenol groups, amido groups, amide groups, amine groups, methyl groups, ethyl groups, isopropyl groups, isobutyl groups, glycerol groups, aromatic groups, phenyl groups, benzene groups, quinone groups, or combinations thereof, and
wherein M comprises one or more alkali metals selected from the group consisting of Li, Na, K, or combinations thereof.

18. The method of claim 15, wherein the first coating comprises lithium-containing hydroquinone (LiHQ).

19. The method of claim 15, wherein the first coating is applied via molecular layer deposition (MLD), wherein the MLD process comprises:
depositing at least one metal source and at least one organic molecule onto the anode, wherein the depositing results in the formation of the metal-containing organic molecule.

20. The method of claim 19, wherein the organic molecule comprises a general formula of H—[O—R]ₙ—OH,
wherein n is an integer of 1 or more, and
wherein R represents the rest of the molecule.

21. The method of claim 19, wherein the organic molecule is selected from the group consisting of diethanolamine (DEA), triethanolamine (TEA), glycerol (GL), triglycerol (TGL), glycerol propoxylate (GLP), glycerol ethoxylate (GLE), trimethylolpropane ethoxylate (TMPE), polyethylene glycol (PEG), chitosan (CS), hydroquinone (HQ), ethylene glycol (EG), diols, triols, polyols, hydroquinone (HQ), tetrafluorohydroquinone (FHQ), 1,4-benzenedicarboxylic acid (BDC), 2,6-naphthalene dicarboxylic acid (NDC) 1,2-ethanediol (EDO), 1,4-butanediol (BDO), 1,6-hexanediole (HDO), fumaric acid (FC), 2,4-hexadiyene-1,6-diol (HDD), 1,2,4-trihydroxybenzene (THB), lactic acid (LC), 2,2-bis(hydroxymethyl)-1,3-propanediole (BHMPD), alpha-thioglycerol (TGL), 1,2,4-butanetriol (BT), 1,2,5,6-hexanetriol (HT), 2-hydroxymethyl-1,3-propanediol (HMPD), 1-(4-nitrophenyl) glycerol (NPGL), or combinations thereof.

22. The method of claim 19, wherein the metal source comprises an alkali metal source selected from the group consisting of Li, Na, K, or combinations thereof.

23. The method of claim 22, wherein the metal source comprises:
a lithium source selected from the group consisting of lithium tert-butoxide (LTB, LiO^{t}Bu), lithium hexamethyldisilazide [LiHMDS, Li(N(SiMe3)2)], lithium trimethylsilanolate (LiTMSO, LiOSiMe3), Li(thd) (thd=2,2,6,6-tetramethyl-3,5-heptanedionate), or combinations thereof;
a sodium source selected from the group consisting of sodium tert-butoxide (NaO^{t}Bu), sodium trimethylsilanolate (NaTMSO), Li(thd) ((thd=2,2,6,6-tetramethyl-3,5-heptanedionate)), or combinations thereof; or
a potassium source selected from the group consisting of potassium tert-butoxide (KO^{t}Bu), potassium trimethylsilanolate (KTMSO), K(thd) ((thd=2,2,6,6-tetramethyl-3,5-heptanedionate)), or combinations thereof.

24. The method of claim 15, wherein the second coating is applied via atomic layer deposition (ALD), wherein the ALD process combines at least one lithium precursor, at least one sulfur precursor, and at least one metal precursor to form the lithium metal sulfide.

25. The method of claim 24,
wherein the lithium precursor is selected from the group consisting of lithium tert-butoxide (LTB, LiO^{t}Bu), lithium hexamethyldisilazide (LiHMDS, Li(N(SiMe₃)₂), lithium trimethylsilanolate (LiTMSO, LiOSiMe₃), Li(2,2,6,6-tetramethyl-3,5-heptanedionate) (Li(thd)), or combinations thereof;
wherein the sulfur precursor is selected from the group consisting of H₂S, di-tert-butyl disulfide (TBDS), or combinations thereof; and
wherein the metal precursor is selected from the group consisting of an aluminum precursor, tris(dimethylamido)aluminum (TDMA-Al), a zinc precursor, diethylzinc (DEZ), a zirconium precursor, tetraki(dimethylamido)zirconium (TDMA-Zr), a gallium precursor, tris(dimethylamido)gallium (TDMA-Ga), or combinations thereof.

26. The method of claim 15, wherein the anode comprises a lithium anode.

27. The method of claim 15, wherein the cathode comprises lithium nickel manganese cobalt oxides (NMCs), wherein the NMC comprises a layer-structured lithium nickel manganese cobalt oxide, and wherein the NMC comprises the following formula: LiNiₓMn_{y}Co_{z}O₂, wherein x+y+z=1.

28. The method of claim 15, wherein the energy storage device comprises a battery.

29. The method of claim 28, wherein the battery is selected from the group consisting of lithium metal batteries, Li∥NMC lithium metal batteries (LMBs), lithium ion batteries, or combinations thereof.
